(19) United States
(12) Patent Application Publication
(10) Pub. No.: US 2010/0280653 A1
(43) Pub. Date: Nov. 4, 2010

(54) SUBSTRATE PROCESSING APPARATUS AND SEMICONDUCTOR DEVICE MANUFACTURING METHOD

(75) Inventor: Yukinori ABURATANI, Toyama (JP)

Correspondence Address: BRUNDIDGE & STANGER, P.C., 2318 MILL ROAD, SUITE 1020, ALEXANDRIA, VA, 22314, US

(73) Assignee: Hitachi-Kokusai Electric Inc., Tokyo (JP)

(21) Appl. No.: 12/760,113

(22) Filed: Apr. 14, 2010

(30) Foreign Application Priority Data
May 1, 2009 (JP) 2009-111711
Mar. 23, 2010 (JP) 2010-065448

(51) Int. Cl. H01L 21/677; G06F 7/00

(52) U.S. Cl. 700/228

(57) ABSTRACT

There is provided a substrate processing apparatus capable of reducing a substrate carrying time. The substrate processing apparatus comprises a transfer machine configured to carry a substrate, a holding part configured to hold the substrate on the transfer machine, and a detector configured to detect whether the substrate is held on the transfer machine based on an operation of the holding part.

### CROSS-REFERENCE TO RELATED PATENT APPLICATION

This U.S. non-provisional patent application claims priority under 35 U.S.C. §119 of Japanese Patent Application Nos. 2009-111711, filed on May 1, 2009, and 2010-065448, filed on Mar. 23, 2010, in the Japanese Patent Office, the entire contents of which are hereby incorporated by reference.

### BACKGROUND OF THE INVENTION

1. Field of the Invention

The present invention relates to a substrate processing apparatus and a semiconductor device manufacturing method.

2. Description of the Prior Art

In a substrate processing apparatus, if a substrate is not carried to a predetermined placement position during a substrate carrying operation, the substrate may be broken, or the operation of the substrate processing apparatus may be stopped. Therefore, in a conventional substrate processing apparatus, a wafer alignment device (aligner) is used to align a substrate so that the substrate can be carried to a predetermined placement position, and moreover, a substrate carrying operation is carried out at a low speed to prevent a substrate position misalignment during the substrate carrying operation.

Patent Document 1 discloses a substrate processing apparatus, which includes a wafer detecting unit configured to detect a capacitance variation and a conductor configured to function as an electric field shield, for precisely detecting a substrate even through the substrate has a high transmittance, simply securing an installation space for a substrate detecting device, and preventing interference between the substrate detecting device and a substrate carrying destination.

[Patent Document 1] Japanese Unexamined Patent Application Publication No. 2000-31246

However, according to the conventional art, a substrate aligning process is required in a substrate carrying sequence, and moreover, it is necessary to carry a substrate at a low speed. Therefore, it takes much time to perform a substrate carrying process.

### SUMMARY OF THE INVENTION

An object of the present invention is to provide a substrate processing apparatus capable of reducing a substrate carrying time.

According to an aspect of the present invention, there is provided a substrate processing apparatus comprising: a transfer machine configured to carry a substrate; a holding part configured to hold the substrate on the transfer machine; and a detector configured to detect whether the substrate is held on the transfer machine based on an operation of the holding part.

Preferably, the substrate processing apparatus may further comprise an ultrasonic detector configured to detect whether the substrate exists on the transfer machine by using ultrasonic waves.

According to another aspect of the present invention, there is provided a semiconductor device manufacturing method comprising: placing a substrate on a transfer machine configured to carry the substrate; holding the substrate placed on the transfer machine; detecting whether the substrate is held on the transfer machine based on an action of holding the substrate; detecting whether the substrate exists on the transfer machine; if it is determined that the substrate is not held on the transfer machine and it is determined that the substrate exists on the transfer machine, stopping carrying of the substrate.

### BRIEF DESCRIPTION OF THE DRAWINGS

FIG. 1 is a perspective view illustrating a substrate processing apparatus according to an embodiment of the present invention.

FIG. 2 is a side view illustrating the substrate processing apparatus according to an embodiment of the present invention.

FIG. 3 is a top view illustrating the substrate processing apparatus according to an embodiment of the present invention.

FIG. 4 is a perspective view illustrating a wafer transfer device 52 used in accordance with an embodiment of the present invention.

FIG. 5 is a front view illustrating the wafer transfer device 52 used in accordance with an embodiment of the present invention.

FIG. 6A and FIG. 6B are schematic views illustrating tweezers 56 and the surrounding structure of the tweezers 56 used in accordance with an embodiment of the present invention, in which FIG. 6A is a top view illustrating the tweezers 56 and a connection part 106, and FIG. 6B is a side view illustrating the tweezers 56.

FIG. 7 is a block diagram illustrating a main control unit 134 and other main parts of the substrate processing apparatus according to an embodiment of the present invention.

FIG. 8A to FIG. 8C are views illustrating a tweezers sensor 130 used in accordance with an embodiment of the present invention, in which FIG. 8A illustrates the case where a gripper 126 is placed in a retracted position, FIG. 8B illustrates the case where the gripper 126 is placed in a holding position, and FIG. 8C illustrates the case where the gripper 126 is in an extended position.

FIG. 9A to FIG. 9C are views illustrating the tweezers sensor 130 used in accordance with an embodiment of the present invention, in which FIG. 9A illustrates the case where a gripper 126 is placed in a retracted position, FIG. 9B illustrates the case where the gripper 126 is placed in a holding position, and FIG. 9C illustrates the case where the gripper 126 is in an extended position.

FIG. 10 is a flowchart illustrating a sequence of wafer carrying operations of the wafer transfer device 52 used in accordance with an embodiment of the present invention.

### DETAILED DESCRIPTION OF THE PREFERRED EMBODIMENTS

An embodiment of the present invention will be described hereinafter with reference to the attached drawings. According to the embodiment of the present invention, a substrate processing apparatus 10 is configured as, for example, a semiconductor device manufacturing apparatus that performs a processing process in a semiconductor device manufacturing method.

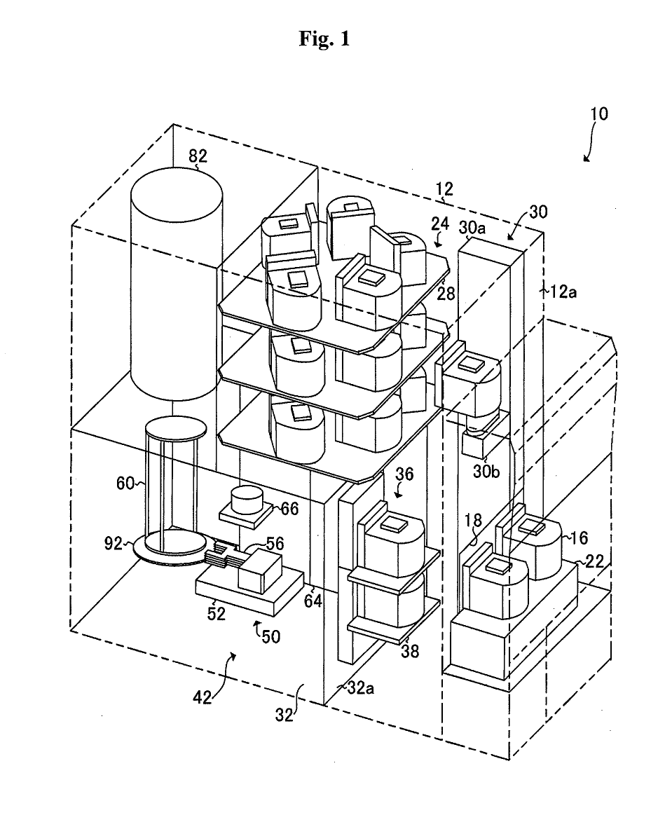

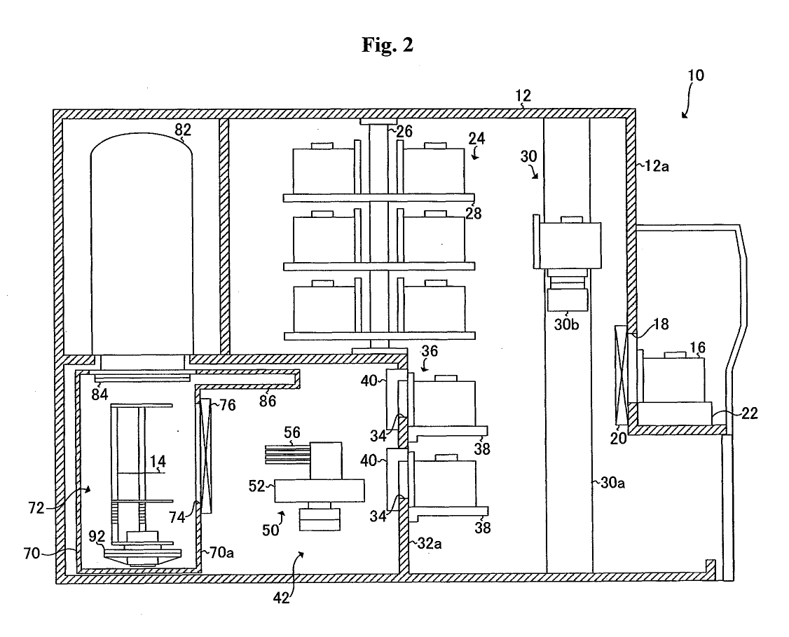

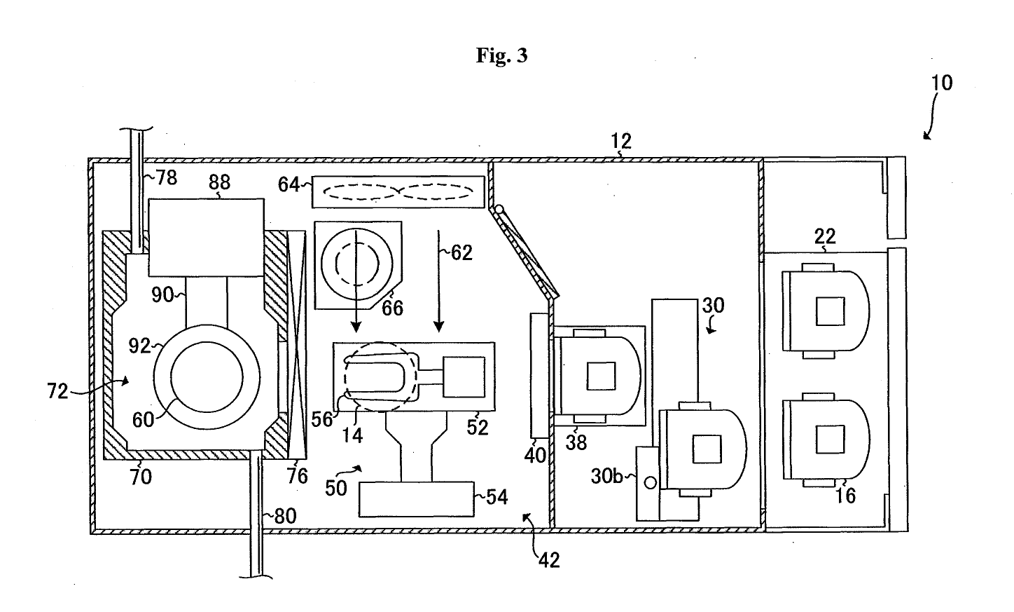

With reference to FIG. 1 to FIG. 3, the overall structure of the substrate processing apparatus 10 will be described in brief. FIG. 1 is a perspective view illustrating the substrate processing apparatus 10 according to an embodiment of the present invention, and FIG. 2 is a side view illustrating the substrate processing apparatus 10. FIG. 3 is a top view illustrating the substrate processing apparatus 10.

The substrate processing apparatus 10 is a batch type vertical semiconductor device manufacturing apparatus and includes a case 12 in which main parts are disposed. In the substrate processing apparatus 10, FOUPs (front opening unified pods, hereinafter referred to as pods) 16, which are substrate containers configured to accommodate substrates such as wafers 14 made of silicon, are used as wafer carriers.

At a front wall 12a of the case 12, a pod carrying entrance 18 is formed to connect the inside and outside of the case 12, and the pod carrying entrance 18 is configured to be opened and closed by a front shutter 20. At the front side of the pod carrying entrance 18, a load port 22 is installed such that pods 16 can be placed on the load port 22 and the positions of the pods 16 can be aligned. Pods 16 are delivered between an in-process carrying device (not shown) and the load port 22.

Near the center upper part of the inside of the case 12 in a front-to-rear direction, a rotary pod shelf 24 is installed such that a plurality of pods 16 can be stored on the rotary pod shelf 24. The rotary pod shelf 24 includes a pillar 26 which is vertically erected and is capable of being intermittently rotated on a horizontal plane, and a plurality of shelf plates 28 which are radially supported by the pillar 26, for example, in vertical three stages. It is configured such that a plurality of pods 6 are placed and stored on each of the shelf plates 28.

Between the load port 22 and the rotary pod shelf 24 in the case 12, a pod carrying device 30 is installed, and the pod carrying device 30 includes a pod elevator 30a capable of holding and elevating a pod 16, and a pod carrying mechanism 30b. The pod carrying device 30 is configured to carry a pod 16 among the load port 22, the rotary pod shelf 24, and pod openers 36 (described later) by continuous operations of the pod elevator 30a and the pod carrying mechanism 30b.

Near the center lower part of the inside of the case 12 in the front-to-rear direction, a sub frame 32 is constructed to extend to the rear end of the case 12. At a front wall 32a of the sub frame 32, for example, a pair of first wafer carrying entrances 34 is formed and vertically aligned in two stages so as to carry wafers 14 into and out of the sub frame 32 through the first wafer carrying entrances 34, and a pair of pod openers 36 are installed at the upper and lower stages of the first wafer carrying entrances 34, respectively.

The pod openers 36 include stages 38 on which pods 16 can be placed, and cap attachment/detachment mechanisms 40 configured to attach and detach caps (covers) of pods 16. Each of the pod openers 36 is configured to attach and detach a cap of a pod 16 installed on the stage 38 by using the cap attachment/detachment mechanism 40 so as to close and open a wafer entrance of the pod 16.

The sub frame 32 forms a transfer chamber 42 which is fluidically isolated from a space where the pod carrying device 30 or the rotary pod shelf 24 is installed. In a front region of the transfer chamber 42, a wafer transfer mechanism 50 is installed. The wafer transfer mechanism 50 includes a wafer transfer device 52 capable of rotating or straightly moving wafers 14 on a horizontal plane, and a wafer transfer device elevator 54 configured to lift or lower the wafer transfer device 52. By continuously operating the wafer transfer device 52 and the wafer transfer device elevator 54 and using tweezers 56 of the wafer transfer device 52 as wafer placement parts, wafers 14 can be charged into and discharged from a boat 60 which is a substrate holding tool.

The boat 60 includes a plurality of holding members and is configured to hold a plurality of wafers 14 (for example, about fifty to one hundred twenty five wafers 14) in a state where the wafers 14 are horizontally positioned with the centers of the wafers 14 being vertically aligned.

At a side of the transfer chamber 42 opposite to the wafer transfer device elevator 54, a cleaning unit 64 including a supply fan and a dust filter is installed to supply a cleaned atmosphere or inert gas as clean air 62. In addition, between the cleaning unit 64 and the wafer transfer device 52, a notch aligning device 66 is installed as a substrate matching device to align circumferential positions of wafers 14.

After clean air 62 blown from the cleaning unit 64 flows along the wafer transfer device 52 and the notch aligning device 66, the clean air 62 is sucked into a duct (not shown) to the outside of the case 12 or is circulated back to a suction side of the cleaning unit 64, that is, a primary side (supply side) of the cleaning unit 64, so as to be blown into the transfer chamber 42 again.

An airtight frame 70 (hereinafter referred to as a pressure-resistant frame) that can be kept at atmospheric pressure or lower (hereinafter also referred to as a negative pressure) is installed in a rear region of the transfer chamber 42, and the pressure-resistant frame 70 forms a loadlock chamber 72 which is a loadlock type standby chamber having a sufficient volume for accommodating the boat 60.

At a front wall 70a of the pressure-resistant frame 70, a second wafer carrying entrance 74 is formed for carrying wafers 14 into and out of the pressure-resistant frame 70, and the second wafer carrying entrance 74 is configured to be opened and closed by a gate valve 76. A gas supply pipe 78 configured to supply inert gas such as nitrogen gas into the loadlock chamber 72, and an exhaust pipe 80 configured to exhaust the loadlock chamber 72 to a negative pressure are connected to a pair of sidewalls of the pressure-resistant frame 70, respectively.

At the upper side of the loadlock chamber 72, a process furnace 82 is installed. The bottom side of the process furnace 82 is configured to be opened and closed by a furnace port gate valve 84. At the upper end of the front wall 70a of the pressure-resistant frame 70, a furnace port gate valve cover 86 is installed to receive the furnace port gate valve 84 when the bottom side of the process furnace 82 is opened.

At the pressure-resistant frame 70, a boat elevator 88 is installed to lift and lower the boat 60. A seal cap 92 functioning as a cover is horizontally fixed to an arm 90 which is connected to the boat elevator 88 as a connection part. The seal cap 92 is configured to vertically support the boat 60 and close the bottom side of the process furnace 82.

Next, the wafer transfer device 52 will be described in detail.

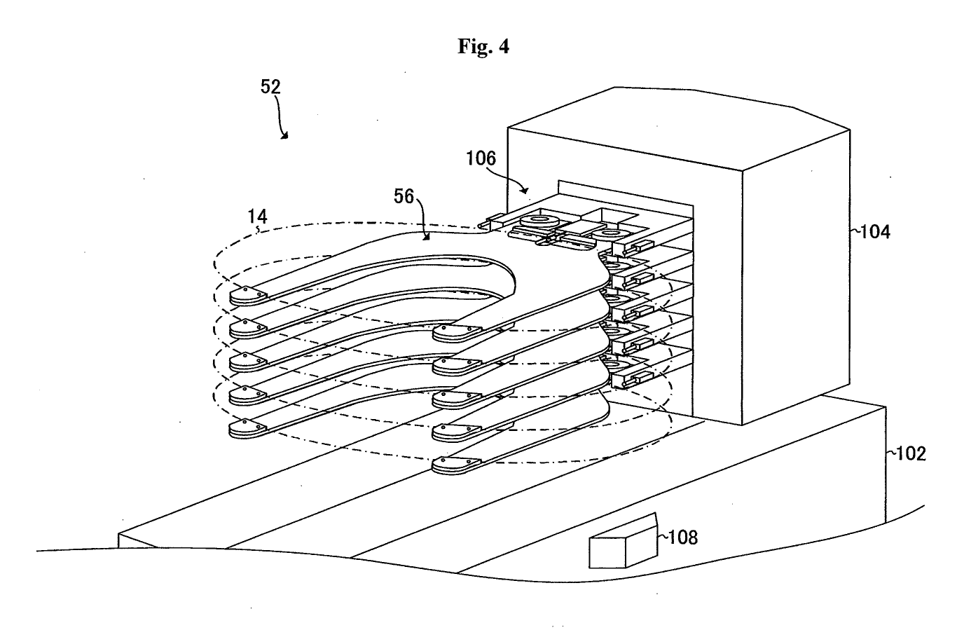

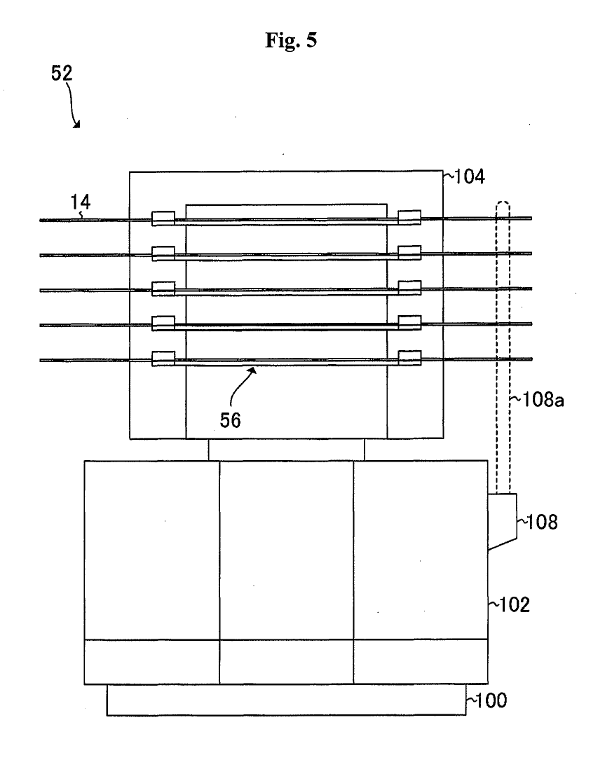

FIG. 4 is a perspective view illustrating the wafer transfer device 52, and FIG. 5 is a front view illustrating the wafer transfer device 52.

The wafer transfer device 52 includes a rotary actuator 100, a linear actuator 102 installed on the surface of the rotary actuator 100, a transfer table 104 installed on the surface of the linear actuator 102, and tweezers 56 fixed to the transfer table 104 through connection parts 106. The rotary actuator 100 is configured to rotate the linear actuator 102 on a horizontal plane. The linear actuator 102 is configured to move the transfer table 104 horizontally. At the transfer table 104, the tweezers 56 (for example, five pairs of tweezers) configured to hold the bottom sides of wafers 14 are horizontally oriented and arranged at regular intervals with the connection parts 106 being disposed therebetween.

At a position below the wafers 14 placed on the tweezers 56, for example, at a lateral side of the linear actuator 102, a transfer device sensor 108 is installed to detect whether a wafer 14 is on the wafer transfer device 52. The transfer device sensor 108 is configured to monitor all the wafers 14 placed on the tweezers 56 and detect existence of a wafer 14 if a wafer 14 is placed on any one of the plurality of pairs of tweezers 56. For example, the transfer device sensor 108 may be a reflective ultrasonic sensor that is not affected by surface conditions of a wafer 14. Since an ultrasonic sensor has a proper detection range 108a, although a wafer pitch is changed, a wafer 14 can be detected as long as the wafer 14 is within the detection range 108a of the ultrasonic sensor. In addition, even when the ultrasonic sensor makes interference with a surrounding device, the possibility of a detection error is low. For example, it may be determined as an ON-state by the transfer device sensor 108 if there is a wafer 14 on the wafer transfer device 52 and as an OFF-sate if there is no wafer 14 on the wafer transfer device 52.

Next, the tweezers 56 of the wafer transfer device 52, and the surrounding structure thereof will be described.

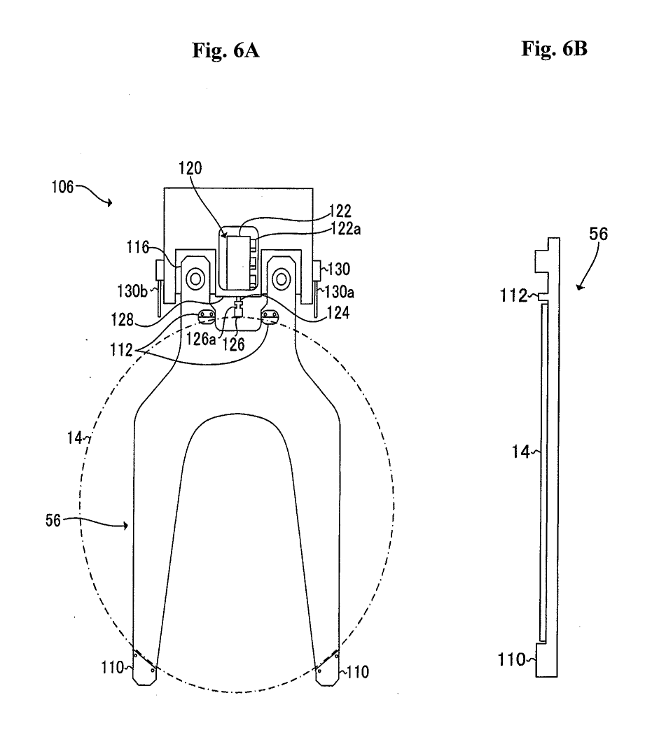

FIG. 6A and FIG. 6B are schematic views illustrating the tweezers 56 and the surrounding structure of the tweezers 56. FIG. 6A is a top view illustrating the tweezers 56 and the connection part 106, and FIG. 6B is a side view illustrating the tweezers 56.

The tweezers 56 is formed of a plate-shaped member having two legs, and a wafer 14 is placed on the surface of the tweezers 56. At the tips of the legs of the tweezers 56, a pair of tip-side edge grips 110 is installed to align the position of the tip edge of the wafer 14 placed on the tweezers 56. In addition, at the rear side of the tweezers 56 (at the side of the connection part 106), rear-side edge grips 112 are installed to align the position of the rear edge of the wafer 14. For example, the tip-side edge grips 110 and the rear-side edge grips 112 are made of resin blocks having a predetermined thickness to prevent the wafer 14 from slipping down from the tweezers 56. In addition, the tweezers 56 includes joints 116 so that the tweezers 56 can be fixed to the connection part 106 through the joints 116.

The connection part 106 includes a wafer holding part 120 configured to hold the wafer 14 placed on the tweezers 56, and a tweezers sensor 130 configured to detect the wafer 14 held on the tweezers 56.

The wafer holding part 120 includes an air cylinder 122 as a driving device, a shaft 124 that can be extended by the air cylinder 122 in a direction from the connection part 106 to the tweezers 56, and a gripper 126 installed on the tip of the shaft 124 for pushing the wafer 14.

The air cylinder 122 is installed in a manner such that a barrier wall 128 is disposed between the air cylinder 122 and the tweezers 56. Therefore, after the wafer 14 is processed, heat transfer from the wafer 14 can be blocked by the barrier wall 128, and thus the air cylinder 122 can be protected from thermal degradation or damage. In addition, the air cylinder 122 includes a pipe 122a such as a cleaning vacuum line functioning as an air inlet/outlet and a contaminant suction port. The pipe 122a is disposed at a side opposite to pipes 122a of upper and lower stacked air cylinders 122. That is, the air cylinders 122 are stacked in a manner such that sides of the air cylinders 122 at which the pipes 122a are disposed are alternated. Owing to this, pipes or wires are not placed only on one side, and thus space can be effectively used.

For example, the gripper 126 is made of a resin block having a cylindrical shape. Therefore, although the shaft 124 on which the gripper 126 is installed is rotated, the wafer 14 pushed by the gripper 126 is less affected, and thus an additional space may be unnecessary to attach a guide to prevent rotation of the shaft 124. In addition, a groove 126a is formed in the gripper 126 so that the outer diameter of the gripper 126 at the groove 126a is smaller than the outer diameter of the gripper 126 at the tip that pushes the wafer 14.

The wafer 14 is placed at a predetermined position of the tweezers 56 with a constant distance (gap) from the tip-side edge grips 110 and the rear-side edge grips 112, and as the shaft 124 is extended by the air cylinder 122, the rear side of the wafer 14 is pushed by the gripper 126. The pushed wafer 14 slips toward the tip side of the tweezers 56 and makes contact with the tip-side edge grips 110. In this way, the wafer 14 is placed and held at a fixed position between the gripper 126 pushing the wafer 14 toward the tip side and the tip-side edge grips 110. In a process of carrying a wafer 14, the wafer 14 is held at the same fixed position of the tweezers 56 each time the wafer 14 is placed on the tweezers 56, and thus a horizontal position misalignment of the wafer 14 can be prevented. In addition, since the wafer 14 is held on the tweezers 56 in a clamped state, movement or falling of the wafer 14 from the wafer transfer device 52 can be prevented, and a carrying operation can be performed at a high speed.

For example, the tweezers sensor 130 is configured by a transmissive fiber sensor having high heat resistance. A phototransmitter 130a and a photoreceiver 130b of the tweezers sensor 130 are installed with the gripper 126 of the wafer holding part 120 being disposed therebetween in a horizontal direction. By using a transmissive fiber sensor as the tweezers sensor 130, the possibility of wrong detection reduces, and size reduction is possible.

Alternatively, a magnetic sensor or a photo sensor may be used as the tweezers sensor 130.

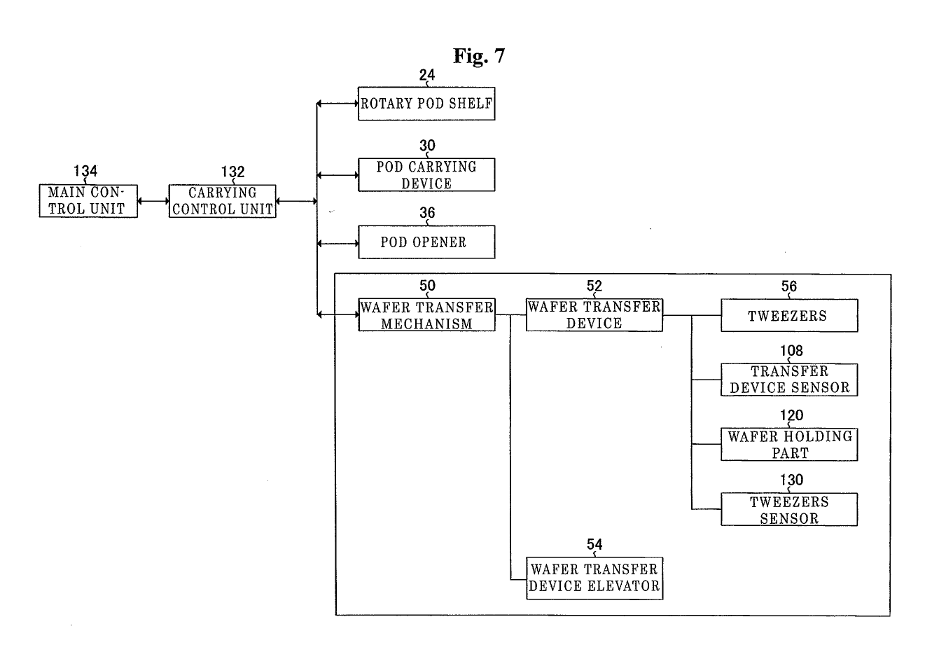

FIG. 7 is a block diagram illustrating a main control unit 134 and other main parts of the substrate processing apparatus 10.

A carrying control unit 132 is electrically connected to the rotary pod shelf 24, the pod carrying device 30, the pod openers 36, and the wafer transfer mechanism 50. The carrying control unit 132 is configured to control a carrying operation to carry wafers 14 or pods 16 to desired positions at desire times, and the carrying control unit 132 is electrically connected to the main control unit 134 that controls the overall operation of the substrate processing apparatus 10.

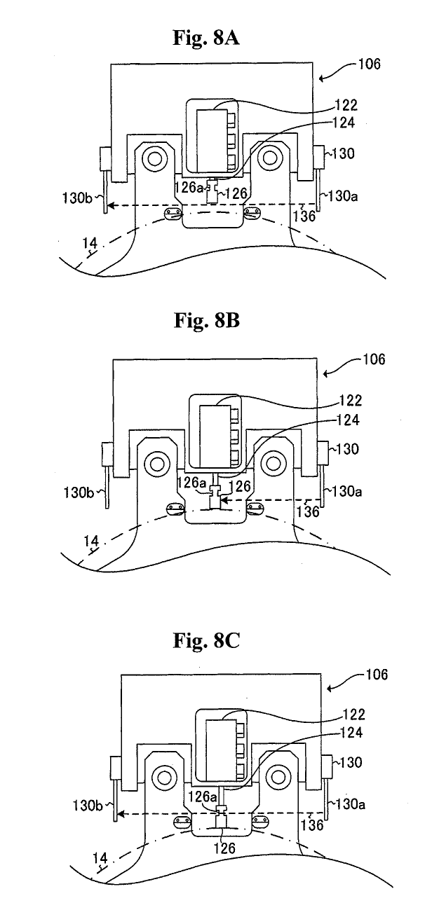

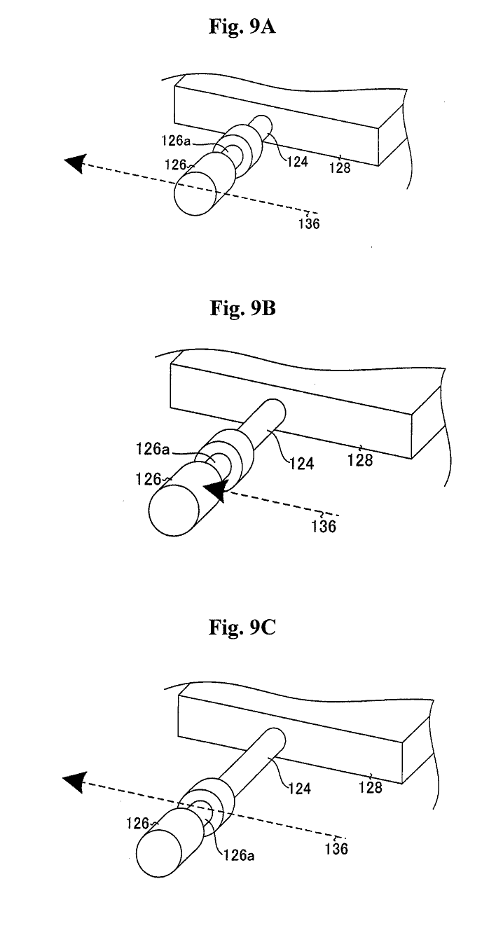

With reference to FIG. 8 and FIG. 9, an explanation will be given on how the tweezers sensor 130 of the connection part 106 detects a wafer 14.

FIG. 8A to FIG. 8C are top views illustrating the connection part 106. FIG. 9A to FIG. 9C are perspective view illustrating the gripper 126. FIG. 8A and FIG. 9A illustrate the case where the gripper 126 is placed in a retracted position; FIG. 8B and FIG. 9B illustrate the case where the gripper 126 is placed in a wafer holding position; and FIG. 8C and FIG. 9C illustrate the case where the gripper 126 is in an extended position.

As the shaft 124 is extended by the air cylinder 122, the gripper 126 is moved to three positions: the retracted position, the wafer holding position, and the extended position. The retracted position is a position where the gripper 126 does not make contact with a wafer 14 although the wafer 14 is placed at a position (rear-side limit position) making contact with the rear-side edge grips 112 (refer to FIG. 8A and FIG. 9A). The wafer holding position is a position where a wafer 14 is disposed between the gripper 126 and the tip-side edge grips 110 after the wafer 14 is pushed by the gripper 126 (refer to FIG. 8B and FIG. 9B).

The extended position is a position where the shaft 124 is fully extended but the gripper 126 does not push a wafer 14 (refer to FIG. 8C and FIG. 9C). For example, the case where the gripper 126 does not push a wafer 14 may be a case where no wafer 14 exist on the tweezers 56 or a case where a wafer 14 is not placed at a predetermined position of the tweezers 56 (for example, when a wafer 14 is placed on the topsides of the tip-side edge grips 110).

In the case where the gripper 126 is placed at the retracted position, light 136 emitted from the phototransmitter 130a of the tweezers sensor 130 passes by the front side of the gripper 126, and then the light 136 arrives at the photoreceiver 130b. In the case where the gripper 126 is placed at the wafer holding position, light 136 emitted from the phototransmitter 130a of the tweezers sensor 130 is blocked by the gripper 126, and thus the light 136 does not arrive at the photoreceiver 130b. Then, the tweezers sensor 130 determines that a wafer 14 is held at a fixed position of the tweezers 56. In the case where the gripper 126 is placed at the extended position, light 136 emitted from the phototransmitter 130a of the tweezers sensor 130 passes through the groove 126a of the gripper 126 so that the light 136 can arrive at the photoreceiver 130b without being blocked by the gripper 126.

In this case, the tweezers sensor 130 determines that no wafer 14 is held at the fixed position of the tweezers 56. For example, the tweezers sensor 130 may determine it as an ON-state when a wafer 14 is held at the fixed position and an OFF-state when no wafer 14 is held at the fixed position. Owing to this structure, it is not necessary to detect the gripper 126 at two positions (the retracted position and the extended position), and thus the tweezers sensor 130 can be configured by only one set. Therefore, spatial limitation can be reduced.

In addition, instead of determining whether a wafer 14 is held at the fixed position only based on whether light is blocked, the tweezers sensor 130 may determine that a wafer 14 is not held at the fixed position when light which is not first blocked is blocked by a movement of the gripper 126 to a wafer pushing position and is then not blocked by a further movement of the gripper 126 to the extended position.

Alternatively, the tweezers sensor 130 may determine that a wafer 14 is not held at the fixed position when a light blocking state lasts for a predetermined time or more.

In addition, since the transfer device sensor 108 also detects existence of a wafer 14, wrong determination may not be easily made when detecting a wafer 14. For example, when a wafer 14 exists at a position of the tweezers 56 different from a predetermined position, although the tweezers sensor 130 may not detect the wafer 14, the transfer device sensor 108 may detect the wafer 14 existing on the tweezers 56.

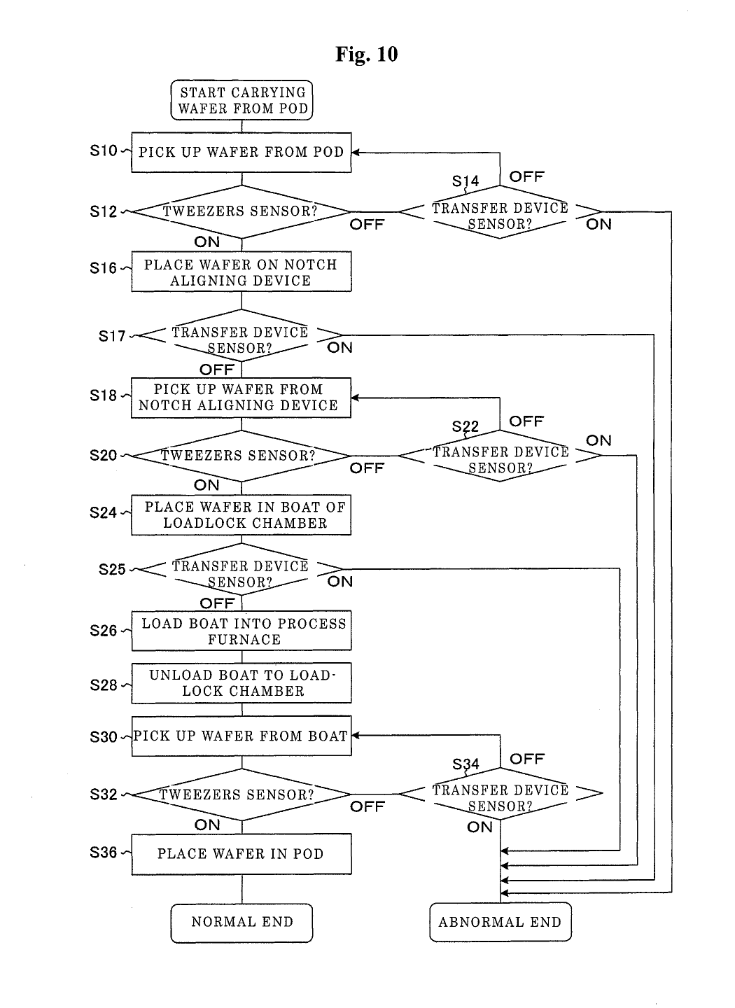

FIG. 10 is a flowchart illustrating a carrying sequence in the transfer chamber 42. Each part of the substrate processing apparatus 10 is controlled by the main control unit 134.

In operation S10, the tweezers 56 of the wafer transfer device 52 picks up a wafer 14 from a pod 16 which is placed on the stage 38 with its wafer entrance being opened.

In operation S12, the tweezers sensor 130 determines whether the wafer 14 is held at the fixed position of the tweezers 56 (ON/OFF determination). If it is determined as an ON-state, the sequence goes to operation S16, and if it is determined as an OFF-state, the sequence goes to operation S14.

In operation S14, the transfer device sensor 108 determines whether the wafer 14 exists at a position of the wafer transfer device 52 different from a predetermined position (ON/OFF determination). If it is determined as an ON-state, it is considered to be abnormal, and the wafer carrying process is stopped. If it is determined as an OFF-state, the sequence goes back to operation S10.

If the wafer carrying process is stopped, this may be reported to an outside area (for example, an operator), for example, by displaying an error message on a display unit (not shown) of the substrate processing apparatus 10 or generating an alarming signal from an alarming unit.

In operation S16, the tweezers 56 places the wafer 14 on the notch aligning device 66.

At this time, whether the wafer 14 is placed on the notch aligning device 66 is confirmed in operation S17 by determining whether the wafer 14 exists on the tweezers 56 using the transfer device sensor 108 (ON/OFF determination). If it is determined as an ON-state, it is considered to be abnormal, and the wafer carrying process is stopped. If it is determined as an OFF-state, the next operation is carried out.

In operation S18, the tweezers 56 picks up the wafer 14 from the notch aligning device 66.

In operation S20, the tweezers sensor 130 determines whether the wafer 14 is held at the fixed position of the tweezers 56 (ON/OFF determination). If it is determined as an ON-state, the sequence goes to operation S24, and if it is determined as an OFF-state, the sequence goes to operation S22.

In operation S22, the transfer device sensor 108 determines whether the wafer 14 exists at a position of the wafer transfer device 52 different from the predetermined position (ON/OFF determination). If it is determined as an ON-state, it is considered to be abnormal, and the wafer carrying process is stopped. If it is determined as an OFF-state, the sequence goes back to operation S18.

In operation S24, the tweezers 56 places the wafer 14 to the boat 60 of the loadlock chamber 72.

At this time, whether the wafer 14 is placed on the boat 60 is confirmed in operation S25 by determining whether the wafer 14 exists on the tweezers 56 using the transfer device sensor 108 (ON/OFF determination). If it is determined as an ON-state, it is considered to be abnormal, and the wafer carrying process is stopped. If it is determined as an OFF-state, the next operation is carried out.

In operation S26, the boat elevator 88 loads the boat 60, in which wafers 14 are placed, into the process furnace 82.

In operation S28, the boat elevator 88 unloads the boat 60, in which wafers 14 are placed, from the process furnace 82 to the gas loadlock chamber 72.

In operation S30, the tweezers 56 picks up a wafer 14 from the boat 60.

In operation S32, the tweezers sensor 130 determines whether the wafer 14 is held at the fixed position of the tweezers 56 (ON/OFF determination). If it is determined as an ON-state, the sequence goes to operation S36, and if it is determined as an OFF-state, the sequence goes to operation S34.

In operation S34, the transfer device sensor 108 determines whether the wafer 14 exists at a position of the wafer transfer device 52 different from the predetermined position (ON/OFF determination). If it is determined as an ON-state, it is considered to be abnormal, and the wafer carrying process is stopped. If it is determined as an OFF-state, the sequence goes back to operation S30.

In operation S36, the tweezers 56 carries the wafer 14 to a pod 16.

However, the present invention is not limited to the above-described embodiment. For example, if the transfer device sensor 108 detects an OFF-state in operations S14, S22, and S34, instead of returning to operations S10, S18, and S30, it may be considered to be abnormal and the carrying process may be stopped.

Next, an operation of the substrate processing apparatus 10 will be described. In the following description, each part of the substrate processing apparatus 10 is controlled by the main control unit 134.

If a pod 16 is fed to the load port 22, the pod carrying entrance 18 is opened by operating the front shutter 20, and the pod 16 is introduced into the case 12 from the load port 22 through the pod carrying entrance 18 by the pod carrying device 30.

The introduced pod 16 is automatically carried and placed onto a predetermined one of the shelf plates 28 of the rotary pod shelf 24 by the pod carrying device 30, and after being temporarily stored, the pod 16 is carried from the shelf plate 28 to one of the pod openers 36 and placed on the stage 38 of the pod opener 36. At this time, the first wafer carrying entrance 34 of the pod opener 36 is closed by the cap attachment/detachment mechanism 40, and clean air 62 is circulated and filled in the transfer chamber 42.

For example, nitrogen gas may be filled in the transfer chamber 42 as clean air 62 to keep the oxygen concentration of the inside of the transfer chamber 42 at 20 ppm or lower, which is much lower than the oxygen concentration of the inside of the case 12 (kept at ambient atmosphere).

When the pod 16 is placed on the stage 38, the opening-side of the pod 16 is pressed by the edge of the first wafer carrying entrance 34 of the front wall 32a of the sub frame 32, and along with this, the cap of the pod 16 is detached by the cap attachment/detachment mechanism 40, so that the wafer entrance of the pod 16 can be opened. Then, the second wafer carrying entrance 74 of the loadlock chamber 72 which is previously kept at atmospheric pressure is opened by operating the gate valve 76, and the tweezers 56 of the wafer transfer device 52 picks up a wafer 14 from the pod 16 through the wafer entrance of the pod 16.

The wafer 14 picked up from the pod 16 is held on the tweezers 56 by the wafer holding part 120, and the tweezers sensor 130 detects whether the wafer 14 is held at the fixed position of the tweezers 56.

If it is determined as an ON-state by the tweezers sensor 130, the carrying process is continued to carry the wafer 14 to the notch aligning device 66 in a state where the wafer 14 is held on the tweezers 56 by the wafer holding part 120. Since a horizontal position misalignment of the wafer 14 is corrected by the wafer holding part 120, it is sufficient that the notch aligning device 66 aligns the circumferential direction of the wafer 14.

On the other hand, if it is determined as an OFF-state by the tweezers sensor 130, the transfer device sensor 108 determines whether the wafer 14 exists on the wafer transfer device 52.

If it is determined as an OFF-state by the transfer device sensor 108, the wafer transfer device 52 is moved back to the pod 16 to pick up a wafer 14.

If it is determined as an ON-state by the transfer device sensor 108, that is, it is determined that the wafer 14 exists at a position different from a predetermined position, the process of carrying the wafer 14 using the wafer transfer device 52 is stopped.

After the circumferential direction of the wafer 14 is aligned by the notch aligning device 66, the wafer 14 is picked up by the tweezers 56 of the wafer transfer device 52 and is detected by the tweezers sensor 130.

At this time, if it is determined as an ON-state by the tweezers sensor 130, the carrying process is continued to introduce the wafer 14 into the loadlock chamber 72 through the second wafer carrying entrance 74 in a state where the wafer 14 is held on the tweezers 56 by the wafer holding part 120, and to transfer and charge the wafer 14 into the boat 60 (wafer charging). After the wafer transfer device 52 delivers the wafer 14 to the boat 60, the wafer transfer device 52 returns to the pod 16 for charging the next wafers 14 into the boat 60.

On the other hand, if it is determined as an OFF-state by the tweezers sensor 130, the transfer device sensor 108 determines whether the wafer 14 exists on the wafer transfer device 52.

If it is determined as an OFF-state by the transfer device sensor 108, the wafer transfer device 52 returns to the notch aligning device 66 to pick up the wafer 14.

If it is determined as an ON-state by the transfer device sensor 108, that is, if it is determined that the wafer 14 exists on a position different from a predetermined position, the process of carrying the wafer 14 using the wafer transfer device 52 is stopped.

While wafers 14 are charged into the boat 60 from one (for example, the upper one) of the pod openers 36 by the wafer transfer device 52, another pod 16 is concurrently carried to the other (for example, the lower one) of the pod openers 36 from the rotary pod shelf 24 or the load port 22 by the pod carrying device 30, and the other pod opener 36 opens the wafer entrance of the other pod 16.

After a predetermined number of wafers 14 are charged into the boat 60, the second wafer carrying entrance 74 is closed by the gate valve 76, and the loadlock chamber 72 is vacuum-evacuated through the exhaust pipe 80 to a low pressure.

If the pressure of the loadlock chamber 72 is reduced to a pressure equal to the inside pressure of the process furnace 82, the bottom side of the process furnace 82 is opened by operating the furnace port gate valve 84. At this time, the furnace port gate valve 84 is inserted and accommodated in the furnace port gate valve cover 86.

Next, the seal cap 92 is lifted by the arm 90 of the boat elevator 88 so that the boat 60 supported on the seal cap 92 can be loaded into the process furnace 82 (boat loading).

After the loading operation, the wafers 14 are processed in the process furnace 82.

After the wafers 14 are processed, the boat 60 is unloaded by the boat elevator 88, and after the inside pressure of the loadlock chamber 72 is returned to atmospheric pressure, the gate valve 76 is opened.

The wafer 14 charged in the boat 60 unloaded from the process furnace 82 is picked up by the tweezers 56 of the wafer transfer device 52 and is detected by the tweezers sensor 130.

At this time, if it is determined as an ON-state by the tweezers sensor 130, the process of carrying the wafer 14 is continued to carry the wafer 14 in a state where the wafer 14 is held on the tweezers 56 by the wafer holding part 120, and to accommodate the wafer 14 into the pod 16 placed on the stage 38. Thereafter, in the reverse order, the wafer 14 and the pod 16 are discharged to the outside of the case 12.

On the other hand, if it is determined as an OFF-state by the tweezers sensor 130, the transfer device sensor 108 determines whether the wafer 14 exists on the wafer transfer device 52.

If it is determined as an OFF-state by the transfer device sensor 108, the wafer transfer device 52 returns to the boat 60 to pick up a wafer 14.

If it is determined as an ON-state by the transfer device sensor 108, that is, if it is determined that the wafer 14 exists at a position different from the predetermined position, the process of carrying the wafer 14 using the wafer transfer device 52 is stopped.

The present invention is not limited to the above-described embodiment. For example, if it is determined as an OFF-state by the transfer device sensor 108, it may be considered to be abnormal, and the wafer carrying process may be stopped.

In addition, although the notch aligning device 66 is used in the above-described embodiment, if it is unnecessary to align the circumferential direction of a wafer, the notch aligning device 66 may be not used, and thus the number of operations may be reduced.

According to the present invention, there is provided a substrate processing apparatus capable of reducing a substrate carrying time.

What is claimed is:

1. A substrate processing apparatus comprising:
a transfer machine configured to carry a substrate;
a holding part configured to hold the substrate on the transfer machine; and
a detector configured to detect whether the substrate is held on the transfer machine based on an operation of the holding part.

2. The substrate processing apparatus of claim 1, further comprising an ultrasonic detector configured to detect whether the substrate exists on the transfer machine by using ultrasonic waves.

3. A semiconductor device manufacturing method comprising:
placing a substrate on a transfer machine configured to carry the substrate;
holding the substrate placed on the transfer machine;
detecting whether the substrate is held on the transfer machine based on an action of holding the substrate;
detecting whether the substrate exists on the transfer machine;
if it is determined that the substrate is not held on the transfer machine and it is determined that the substrate exists on the transfer machine, stopping carrying of the substrate.
